(19) United States
(12) Patent Application Publication
(10) Pub. No.: US 2015/0348948 A1
(43) Pub. Date: Dec. 3, 2015

(54) MULTIPLE DIE LIGHT EMITTING DIODE (LED) COMPONENTS AND METHODS OF FABRICATING SAME

(71) Applicant: Cree, Inc., Durham, NC (US)

(72) Inventors: Peter S. Andrews, Durham, NC (US); Christopher P. Hussell, Cary, NC (US); Fan Zhang, Goleta, CA (US); Theodore D. Lowes, Lompoc, CA (US)

(73) Assignee: Cree, Inc., Durham, NC (US)

(21) Appl. No.: 14/289,305

(22) Filed: May 28, 2014

(51) Int. Cl. H01L 25/075; H01L 33/60; H01L 33/54; H01L 33/62; H01L 33/48; H01L 33/50

(52) U.S. Cl. CPC H01L 25/0753; H01L 33/486; H01L 33/507; H01L 33/505; H01L 33/54; H01L 33/62; H01L 33/60

(57) ABSTRACT

A Light Emitting Diode (LED) component includes discrete LED dies that are spaced apart from one another. An electrical connection element is provided adjacent the LED dies and configured to electrically connect the discrete LED dies in series and/or in parallel. A unitary optically transparent structure is provided on the second faces of the LED dies remote from the anode and cathode contacts, that spans the plurality of LED dies. The LED component is unsupported by a submount that spans adjacent ones of the LED dies. The electrical connection element may be a patterned metal sheet that is patterned to electrically connect the discrete LED dies in series and/or in parallel. The electrical connection element may also be wire bonds adjacent the LED dies that are arranged to electrically connect the discrete LED dies in series and/or in parallel.

### BACKGROUND

Various embodiments described herein relate to light emitting devices and assemblies and methods of manufacturing the same, and more particularly, to Light Emitting Diodes (LEDs), assemblies thereof and fabrication methods therefore.

LEDs are widely known solid-state lighting elements that are capable of generating light upon application of voltage thereto. LEDs generally include a diode region having first and second opposing faces, and include therein an n-type layer, a p-type layer and a p-n junction. An anode contact ohmically contacts the p-type layer and a cathode contact ohmically contacts the n-type layer. The diode region may be epitaxially formed on a substrate, such as a sapphire, silicon, silicon carbide, gallium arsenide, gallium nitride, etc., growth substrate, but the completed device may not include a substrate. The diode region may be fabricated, for example, from silicon carbide, gallium nitride, gallium phosphide, aluminum nitride and/or gallium arsenide-based materials and/or from organic semiconductor-based materials. Finally, the light radiated by the LED may be in the visible or ultraviolet (UV) regions, and the LED may incorporate wavelength conversion material such as phosphor.

An LED component provides a packaged LED die for mounting on a board, such as a Metal Core Printed Circuit Board (MCPCB), flexible circuit board and/or other printed circuit board, along with other electronic components, for example using surface mount technology. An LED component generally includes an LED die, a submount and other packaging elements.

Submounts are generally used in LED components to interpose an LED die and a printed circuit board. The submount may change the contact configuration of the LED die to be compatible with the pads of the printed circuit board. The submount may also be used to support a phosphor layer and/or an encapsulating dome that surrounds the LED die. The submount may also provide other functionality. Thus, a submount may include a receiving element onto which an LED die is mounted using conventional die-attach techniques, to interface the LED die and a printed circuit board. A submount generally has a thickness of at least 100 μm, and in some embodiments at least 150 μm, and in other embodiments at least 200 μm, and generally includes traces (such as on ceramic panels) and/or leads (such as in Plastic Leaded Chip Carrier (PLCC) package).

LEDs are increasingly being used in lighting/illumination applications, with a goal being to provide a replacement for the ubiquitous incandescent light bulb.

### SUMMARY

A Light Emitting Diode (LED) component according to various embodiments described herein includes a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another. An electrical connection element is provided adjacent the first faces of the LED dies and configured to electrically connect the plurality of discrete LED dies in series and/or in parallel. A unitary optically transparent structure is provided on the second faces of the LED dies remote from the anode and cathode contacts, that spans the plurality of LED dies.

In some embodiments, the LED component is unsupported by a submount adjacent the first faces of the LED dies that spans the first faces of adjacent ones of the LED dies. In some embodiments, the electrical connection element comprises a patterned metal sheet adjacent the first faces of the LED dies that is patterned to electrically connect the plurality of discrete LED dies in series and/or in parallel. In other embodiments, the electrical connection element comprises a plurality of wire bonds adjacent the first faces of the LED dies that are arranged to electrically connect the plurality of discrete LED dies in series and/or in parallel.

In some embodiments, the patterned metal sheet comprises first and second opposing faces, the LED dies being disposed on the first face of the patterned metal sheet such that the anode and cathode contacts are adjacent the first face of the patterned metal sheet and in some embodiments the second face of the patterned metal sheet is free of the submount thereon adjacent the plurality of LED dies. In some embodiments, the LED component may further comprise a plurality of solder structures, a respective one of which electrically connects a respective one of the anode and cathode contacts to the patterned metal sheet. The patterned metal sheet is patterned to selectively electrically connect the anode and cathode contacts of the LED dies in series and/or in parallel through the solder structures and to also provide an external anode contact and an external cathode contact for the LED component.

In other embodiments, the LED dies are disposed on the patterned metal sheet such that the anode contacts of adjacent LED dies are adjacent one another and the cathode contacts of adjacent LED dies are adjacent one another, and the patterned metal sheet is patterned to electrically connect the anode contacts of the plurality of LED dies to one another and to electrically connect the cathode contacts of the plurality of LED dies to one another so that the plurality of LED dies are connected in parallel. In still other embodiments, the LED dies are disposed on the patterned metal sheet such that the anode contacts of adjacent LED dies are opposite one another and the cathode contacts of adjacent LED dies are opposite one another, and the patterned metal sheet is patterned to electrically connect the anode contact and the cathode contact of adjacent LED dies to one another so that the plurality of LED dies are connected in series.

In any of the embodiments described above, the LED component may further include a layer comprising luminophoric material on the second faces of the LED dies. In some embodiments, the layer comprising luminophoric material also extends on sidewalls of the LED dies. In some embodiments, the unitary optically transparent structure is a unitary, rigid, optically transparent sheet on the layer comprising luminophoric material, remote from the LED dies. In some embodiments, the unitary, rigid, optically transparent sheets span the plurality of LED dies, and may comprise a glass sheet.

In yet other embodiments, the LED component further comprises an optically transparent structure on a respective LED die, remote from the anode and cathode contacts, and the patterned metal sheet is configured as a polygonal cylinder having a plurality of polygonal cylinder faces, wherein a respective LED die is on a respective polygonal cylinder face and wherein the patterned metal sheet connects adjacent polygonal cylinder faces to one another. The optically transparent structure may comprise a sheet, in some embodiments a rigid sheet and in some embodiments a glass sheet. In other embodiments, the LED component may further comprise an optical coupling material between the optically transparent structure and the layer comprising luminophoric material.

An LED component according to any of the embodiments described above may be provided on a board along with other electronic components, wherein the LED component is free of a submount between the plurality of LED dies and the board.

An LED component according to other embodiments described herein may comprise a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another. The LED component may be unsupported by a submount adjacent the first faces of the LED dies that spans the first faces of adjacent ones of the LED dies, A plurality of wire bonds is provided adjacent the first faces of the LED dies that are configured to electrically connect the plurality of discrete LED dies in series and/or in parallel. A plurality of solder structures are also provided, a respective one of which is on a respective one of the anode and cathode contacts. A unitary optically transparent structure is provided on the second faces of the LED dies remote from the anode and cathode contacts, that spans the plurality of LED dies.

In some embodiments, a layer comprising luminophoric material is provided on the second faces of the LED dies, wherein the layer comprising luminophoric material also extends on sidewalls of the LED dies. An optical coupling material may be provided between the optically transparent structure and the layer comprising luminophoric material. A reflective layer may be provided on the first faces of the LED dies and extending between adjacent ones of the LED dies.

In some embodiments the unitary optically transparent structure comprises a rigid, unitary optically transparent structure, such as a glass sheet. Moreover, in some embodiments, the reflective layer comprises white paint.

In some embodiments, the LED dies are disposed such that the anode contacts of adjacent LED dies are adjacent one another and the cathode contacts of adjacent LED dies are adjacent one another, and the wire bonds are configured to electrically connect the anode contacts of the plurality of LED dies to one another and to electrically connect the cathode contacts of the plurality of LED dies to one another so that the plurality of LED dies are connected in parallel. In other embodiments, the LED dies are disposed such that the anode contacts of adjacent LED dies are opposite one another and the cathode contacts of adjacent LED dies are opposite one another, and the wire bonds are configured to electrically connect the anode contact and the cathode contact of adjacent LED dies to one another so that the plurality of LED dies are connected in series.

In any of the above embodiments, the LED component may be provided on a board along with other electronic components, wherein the LED component is free of a submount between the plurality of LED dies and the board. In some embodiments, the board comprises a contact pad pattern including an external anode contact pad for the LED component, an external cathode contact pad for the LED component and a thermal contact pad for the LED component. A plurality of solder structures also may be provided between the LED component and the board wherein the plurality of solder structures are configured to electrically connect an anode contact to the external anode contact pad, a cathode contact to the external cathode contact pad and an anode contact and/or a cathode contact to the thermal contact pad.

An LED component according to yet other embodiments described herein may comprise a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another. The LED component may be unsupported by a submount adjacent the first faces of the LED dies that spans the first faces of adjacent ones of the LED dies. A patterned metal sheet may also be provided that comprises first and second opposing faces, the LED dies being disposed on the first face of the patterned metal sheet such that the anode and cathode contacts are adjacent the first face of the patterned metal sheet and the second face of the patterned metal sheet is free of the submount thereon adjacent the plurality of LED dies. A plurality of solder structures are provided, a respective one of which electrically connects a respective one of the anode and cathode contacts to the patterned metal sheet.

The patterned metal sheet is patterned to selectively electrically connect the anode and cathode contacts of the LED dies in series and/or in parallel through the solder structures and to also provide an external anode contact and an external cathode contact for the LED component. A layer comprising luminophoric material is provided on the second faces of the LED dies, wherein the layer comprising luminophoric material also extends on sidewalls of the LED dies. A unitary optically transparent structure may be provided on the layer comprising luminophoric material, remote from the LED dies. An optical coupling material is provided between the optically transparent structure and the layer comprising luminophoric material. A reflective layer is also provided on the first faces of the LED dies between the first faces of the LED dies and the patterned metal sheet, and extending between adjacent ones of the LED dies.

In some embodiments, the unitary optically transparent structure comprises a rigid, unitary optically transparent structure that spans the plurality of LED dies. The rigid unitary optically transparent structure may comprise a glass sheet. Moreover, in some embodiments, the reflective layer may comprise white paint.

Moreover, in other embodiments, a discrete optically transparent structure may be provided on a respective LED die, and the patterned metal sheet is configured as a polygonal cylinder, having a plurality of polygonal cylinder faces, wherein a respective LED die is on a respective polygonal cylinder face and wherein the patterned metal sheet connects adjacent polygonal cylinder faces to one another.

In some embodiments, the LED dies are disposed such that the anode contacts of adjacent LED dies are adjacent one another and the cathode contacts of adjacent LED dies are adjacent one another, and the patterned metal sheet is configured to electrically connect the anode contacts of the plurality of LED dies to one another and to electrically connect the cathode contacts of the plurality of LED dies to one another so that the plurality of LED dies are connected in parallel. In other embodiments, the LED dies are disposed such that the anode contacts of adjacent LED dies are opposite one another and the cathode contacts of adjacent LED dies are opposite one another, and the patterned metal sheet is configured to electrically connect the anode contact and the cathode contact of adjacent LED dies to one another so that the plurality of LED dies are connected in series.

In any of the above embodiments, the LED component may be provided on a board along with other electronic components, wherein the LED component is free of a submount between the plurality of LED dies and the board.

LED components may be fabricated according to various embodiments described herein by placing a plurality of discrete LED dies on a carrier sheet in spaced apart relation from one another, a respective LED die comprising first and second opposing faces and an anode contact and a cathode contact on the first face thereof, the plurality of discrete LED dies being oriented on the carrier sheet such that the first faces of adjacent LED dies are adjacent the carrier sheet and the second faces of adjacent LEDs are remote from the carrier sheet. A luminophoric layer is coated on the second faces and sidewalls of the LED dies on the carrier sheet. A unitary optically transparent structure is placed on the second faces of the LED dies so that the unitary optically transparent structure spans the LED dies. The carrier sheet is removed such that the unitary optically transparent structure supports the plurality of discrete LED dies thereon. A plurality of LED dies that are on the unitary optically transparent structure are selectively electrically connected in series and/or in parallel. A reflective layer is applied on the first faces of the LED dies and extending between adjacent ones of the LED dies. Groups of the LEDs that are connected in series and/or in parallel are singulated to provide a plurality of the LED components, a respective LED component being unsupported by a submount adjacent the first faces of the LED dies that spans the first faces of adjacent ones of the LED dies.

In some embodiments, the selectively electrically connecting comprises placing a patterned metal sheet on the first faces of the LED dies that is patterned to electrically connect the plurality of discrete LED dies in series and/or in parallel. In these embodiments, the placing of a patterned metal sheet may be preceded by placing a plurality of solder structures between the anode contacts and the patterned metal sheet, and soldering a respective one of the anode and cathode contacts to the patterned metal sheet using the solder structures. In other embodiments, the patterned metal sheet may be bent into a polygonal cylinder having a plurality of polygonal cylinder faces, wherein a respective LED die is on a respective polygonal cylinder face and wherein the patterned metal sheet connects adjacent polygonal cylinder faces to one another. In still other embodiments, the selectively electrically connecting comprises selectively wire bonding the anode and cathode contacts to electrically connect the plurality of discrete LED dies in series and/or in parallel.

In some embodiments, the unitary optically transparent structure comprises a glass sheet. Moreover, in some embodiments, placing a unitary optically transparent structure on the second faces of the LED dies is preceded by placing an optical coupling material on the layer comprising luminophoric material.

In some embodiments, the plurality of discrete LED dies are placed on the carrier sheet, such that the anode contacts of adjacent LED dies are adjacent one another and the cathode contacts of adjacent LED dies are adjacent one another. In other embodiments, the plurality of LED dies are placed on the carrier sheet such that the anode contacts of adjacent LED dies are opposite one another and the cathode contacts of adjacent LED dies are opposite one another.

Finally, any of the above embodiments may further comprise mounting the LED component on a board along with other electronic components, without providing a submount between the plurality of LED dies and the board.

### BRIEF DESCRIPTION OF THE DRAWINGS

FIG. 1 is a cross-sectional view of an LED die according to various embodiments described herein.

FIG. 2 is a cross-sectional view of an LED component according to various embodiments described herein.

FIGS. 3 and 4 are plan views of an LED component on a mounting board according to various embodiments described herein.

FIGS. 5 and 6 are plan view of an LED component according to various other embodiments described herein.

FIG. 7 is a perspective view of an LED component according to various embodiments described herein.

FIG. 8 is a cross-sectional view of an LED component according to various other embodiments described herein.

FIG. 9 is a cross-section of an LED component of FIG. 8, mounted on a board according to various embodiments described herein.

FIG. 10 is a cross-sectional view of an LED component according to various other embodiments described herein.

FIG. 11 is a cross-section of an LED component of FIG. 10, mounted on a board according to various embodiments described herein.

FIG. 12 is a plan view of an LED component according to various other embodiments described herein.

FIGS. 13-20 are cross-sectional views of an LED component according to various embodiments described herein during intermediate fabrication steps according to various embodiments described herein.

FIGS. 21-26 are cross-sectional views of an LED component according to various embodiments described herein during intermediate fabrication steps according to various other embodiments described herein.

### DETAILED DESCRIPTION

The present invention now will be described more fully with reference to the accompanying drawings, in which various embodiments are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” another element, it can be directly on the other element or intervening elements may also be present. Furthermore, relative terms such as “beneath” or “overlies” may be used herein to describe a relationship of one layer or region to another layer or region relative to a substrate or base layer as illustrated in the figures. It will be understood that these terms are intended to encompass different orientations of the device in addition to the orientation depicted in the figures. The term “directly” means that there are no intervening elements. As used herein, the term “and/or” includes any and all combinations of one or more of the associated listed items and may be abbreviated as “/”.

As used herein, a layer or region is considered to be “transparent” when at least 50% of the radiation that impinges on the transparent layer or region emerges through the transparent layer or region. Moreover, as used herein, a “rigid” structure is a stiff structure that is unable to bend or be forced out of shape; i.e., not flexible or pliant. A rigid structure may be subject to minimal bending without breaking, but bending beyond this minimal bending will break or deform a rigid structure. As also used herein, a “flexible structure” means a structure that is not rigid. In specific examples of materials used herein, glass is considered to be rigid, whereas silicone is considered to be flexible. Finally, as used herein, a “sheet” means a broad, relatively thin piece, plate or slab of material, such as glass.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional and/or other illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as a rectangle will, typically, have rounded or curved features due to normal manufacturing tolerances. Thus, the regions illustrated in the figures are schematic in nature and their shapes are not intended to illustrate the precise shape of a region of a device and are not intended to limit the scope of the invention, unless otherwise defined herein.

Unless otherwise defined herein, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Some embodiments now will be described generally with reference to gallium nitride (GaN)-based light emitting diodes on silicon carbide (SiC)-based growth substrates for ease of understanding the description herein. However, it will be understood by those having skill in the art that other embodiments of the present invention may be based on a variety of different combinations of growth substrate and epitaxial layers. For example, combinations can include AlGaInP diodes on GaP growth substrates; InGaAs diodes on GaAs growth substrates; AlGaAs diodes on GaAs growth substrates; SiC diodes on SiC or sapphire (Al₂O₃) growth substrates and/or a Group III-nitride-based diode on gallium nitride, silicon carbide, aluminum nitride, sapphire, zinc oxide and/or other growth substrates. Moreover, in other embodiments, a growth substrate may not be present in the finished product. For example, the growth substrate may be removed after forming the light emitting diode, and/or a bonded substrate may be provided on the light emitting diode after removing the growth substrate. In some embodiments, the light emitting diodes may be gallium nitride-based LED devices manufactured and sold by Cree, Inc. of Durham, N.C.

Various embodiments described herein can provide submount-free multiple die LED components that may be ready for mounting on a mounting board, such as a printed circuit board. The LED component includes a plurality of discrete LED dies and an electrical connection element is configured to electrically connect the plurality of discrete LED dies in series and/or in parallel. The electrical connection element may include a patterned metal sheet and/or a plurality of wire bonds. The serial and/or parallel connection can provide high current and/or high voltage LED components, such as a 24 volt LED component. Moreover, the LED component is not supported by a submount that spans the LED dies.

Various embodiments described herein may arise from a recognition that, although useful for mounting LED dies, a submount may require additional processing complexity and/or cost, and may also impact the reliability of the LED component. In contrast, various embodiments described herein provide an electrical connection element that electrically connects the plurality of discrete LED dies in series and/or in parallel, without a submount that spans adjacent ones of the LED dies. Moreover, multiple relatively small LED dies may be used in some embodiments, compared to one or more larger LED dies, which can increase luminous flux by providing additional light extraction surfaces (e.g., more sidewalls).

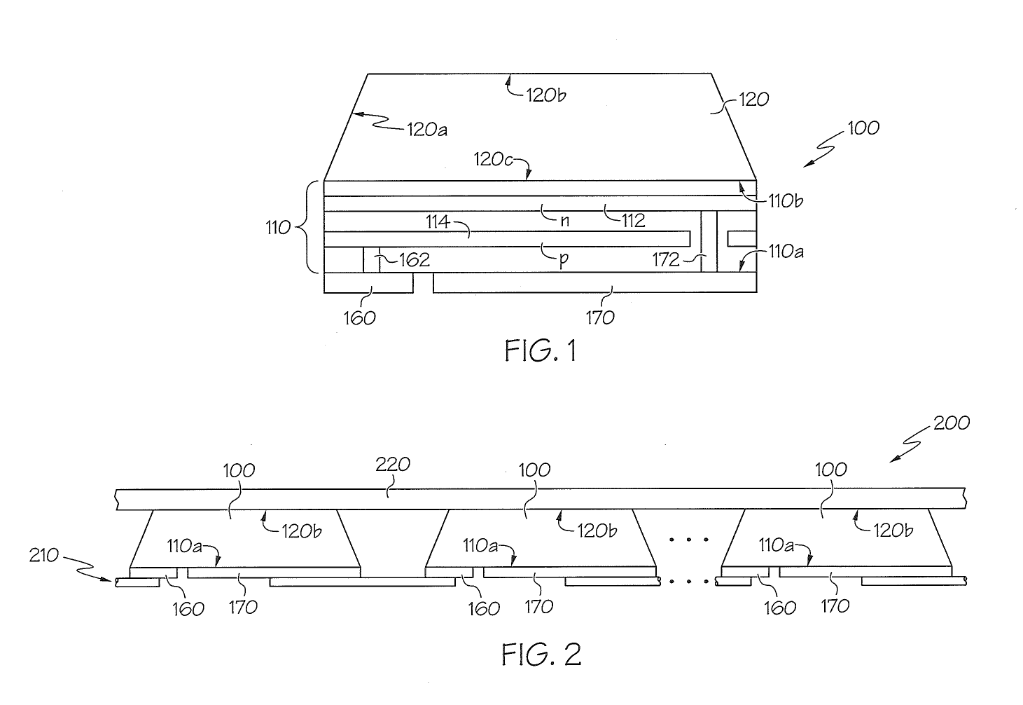

FIG. 1 is a cross-sectional view of a Light Emitting Diode (LED) die, also referred to as an LED chip, according to various embodiments described herein. Referring to FIG. 1, LED die 100 includes a diode region 110 having first and second opposing faces 110a, 110b, respectively, and including therein an n-type layer 112 and a p-type layer 114. Other layers or regions may be provided, which may include quantum wells, buffer layers, etc., that need not be described herein. An anode contact 160 ohmically contacts the p-type layer 114 and extends on the first face 110a. The anode contact 160 may directly ohmically contact the p-type layer 114, or may ohmically contact the p-type layer 114 by way of one or more conductive vias 162 and/or other intermediate layers. A cathode contact 170 ohmically contacts the n-type layer 112 and also extends on the first face 110a. The cathode contact may directly ohmically contact the n-type layer 112, or may ohmically contact the n-type layer 112 by way of one or more conductive vias 172 and/or other intermediate layers. As illustrated in FIG. 1, the anode contact 160 and that cathode contact 170 that both extend on the first face 110a are coplanar, although they need not be coplanar. The diode region 110 also may be referred to herein as an “LED epi region”, because it is typically formed epitaxially on a substrate 120. For example, a Group III-nitride based LED epi 110 may be formed on a silicon carbide growth substrate. In some embodiments, the growth substrate may be present in the finished product. In other embodiments, the growth substrate may be removed. In still other embodiments, another substrate may be provided that is different from the growth substrate.

As also shown in FIG. 1, a transparent substrate 120, such as a transparent silicon carbide growth substrate, is included on the second face 110b of the diode region 110. The transparent substrate 120 includes a sidewall 120a and may also include an inner face 120c adjacent the second face 110b of the diode region 110 and an outer face 120b, remote from the inner face 120c. The outer face 120b may be of smaller area than the inner face 120c. In some embodiments, the sidewall 120a may be stepped, beveled and/or faceted, so as to provide the outer face 120b that is of smaller area than the inner face 120c. In other embodiments, as shown in FIG. 1, the sidewall is an oblique sidewall 120a that extends at an oblique angle, and in some embodiments at an obtuse angle, from the outer face 120b towards the inner face 120c. In yet other embodiments, the sidewall 120a may be orthogonal to the faces.

LED dies 100 configured as was described above in connection with FIG. 1, may be referred to as “horizontal” or “lateral” LEDs, because both the anode and the cathode contacts thereof are provided on a single face of the LED die. Horizontal LEDs may be contrasted with vertical LEDs in which the anode and cathode contacts are provided on opposite faces thereof.

Various other configurations of horizontal LEDs that may be used according to any of the embodiments described herein, are described in detail in U.S. Patent Application Publication 2009/0283787 to Donofrio et al., entitled “Semiconductor Light Emitting Diodes Having Reflective Structures and Methods of Fabricating Same”; U.S. Patent Application Publication 2011/0031502 to Bergmann et al., entitled “Light Emitting Diodes Including Integrated Backside Reflector and Die Attach”; U.S. Patent Application Publication 2012/0193660 to Donofrio et al. entitled “Horizontal Light Emitting Diodes Including Phosphor Particles”; and U.S. Patent Application Publication 2012/0193662 to Donofrio et al. entitled “Reflective Mounting Substrates for Flip-Chip Mounted Horizontal LEDs”, assigned to the assignee of the present application, the disclosures of which are hereby incorporated herein by reference in their entirety as if set forth fully herein.

Other configurations of horizontal LEDs may be embodied by the “Direct Attach” LED chips that are marketed by Cree, Inc., the assignee of the present application, and which are described, for example, in Data Sheets entitled “Direct Attach DA2432™ LEDs” (Data Sheet: CPR3FM Rev., 2011); “Direct Attach DA1000™ LEDs” (Data Sheet: CPR3ES Rev. A, 2010); and “Direct Attach DA3547™ LEDs” (Data Sheet: CPR3EL Rev. D, 2010-2012), the disclosures of which are hereby incorporated herein by reference in their entirety as if set forth fully herein.

In order to simplify the drawings which follow, the internal structure of LED dies 100 will not be illustrated. Rather, the following figures will only illustrate the anode contact 160 and cathode contact 170 of the LED die 100. The LED die 100 comprises first and second opposing faces, wherein the first opposing face is the first face 110a of the diode region and the second face is the second face 110b of the diode region when no substrate is present, or the outer face 120b of the substrate 120 when a substrate 120 is present. The anode contact 160 and the cathode contact 170 are on the first face 110a.

Moreover, in various embodiments described herein, all of the LED dies 100 are indicated as being of the same size and generally rectangular. However, the LED dies 100 may be square or of other shapes, and need not all be the same size or type of LED. Moreover, the anode and cathode contacts 160 and 170, respectively, are all illustrated as being the same size as one another. In other embodiments, however, the anode and cathode contact of a given LED need not be of the same size, and the anode and cathode contacts of the various LEDs need not be the same size or shape as one another. The LED dies may emit different colors of light and may include a phosphor layer thereon. For example, in some embodiments, a combination of white and red LED dies may be provided. Moreover, any number of multiple LED dies 100 may be provided based on the requirements of the LED component 300.

FIG. 2 is a cross-sectional view of an LED component according to various embodiments described herein. Referring to FIG. 2, the LED component 200 includes a plurality of discrete LED dies 100 that are spaced apart from one another. A respective LED die 100 comprises first and second opposing faces 100a and 120b, respectively, and an anode contact and a cathode contact 160, 170, respectively, on the first face 110a of the LED dies. The plurality of discrete LED dies are oriented such that the first faces 110a of adjacent LED dies are adjacent one another and the second faces 120b of adjacent LED dies are adjacent one another. An electrical connection element 210 is also provided adjacent the first faces 110a of the LED dies 100 and configured to electrically contact the plurality of discrete LED dies 110 in series and/or in parallel. Various embodiments of electrical connection elements will be described in detail below. As also illustrated in FIG. 2, the LED component 200 is unsupported by a submount adjacent the first faces 110 of the LED die that spans the first faces 110 of adjacent ones of the LED dies.

Still referring to FIG. 2, a unitary optically transparent structure 220, such as a rigid, unitary optically transparent sheet, for example a glass sheet, is provided on the second faces 120b of the LED dies 110, in some embodiments. The unitary optically transparent structure 220 spans the plurality of LED dies 110. The unitary optically transparent structure 220 can provide mechanical support for the LED component 200. In other embodiments, the optically transparent structure may not be included. In still other embodiments, the unitary optically transparent structure 220 may be a flexible, unitary optically transparent structure, such as a molded silicone-based matrix that is on the second faces 120b of the LED dies, and that may also extend on sidewalls thereof. Such a flexible unitary optically transparent sheet may have a better match to a flexible circuit board, which may alleviate stress on solder joints or other attachment components. Moreover, an LED component with a flexible unitary optically transparent structure 220 may be used with slightly curved or non-planar boards, such as a flexible circuit wrapped around a cylinder. Submount-free, multiple die components are thereby provided.

In some embodiments, the unitary optically transparent structure 220 may be embodied as a glass sheet, such as a D 263° thin borosilicate glass marketed by Schott North America, Inc. and/or similar glass sheets from other manufacturers. In some embodiments, the glass sheet is between about 200 μm and about 1 mm thick. In other embodiments, the glass sheet may be about 700 μm thick. The glass sheet may have an index of refraction of about 1.5 and in some embodiments 1.524. In some embodiments, when a 200 μm thick glass sheet is used, a thick layer of index matching gel may be provided to maintain an overall cubic shape. Using glass thicker than about 700 μm may have diminishing returns, and may be harder to singulate. Moreover, using glass thinner than about 700 μm may provide at least some loss of light. In some embodiments, the glass sheet may have a thickness variation of about +/−25 μm and, in a given piece of the glass sheet, the thickness variation may be about +/−5 μm. It will be understood that other rigid transparent sheets may also be employed in other embodiments. It will also be understood that flexible transparent sheets may also be employed in yet other embodiments.

As will be described in more detail below, in some embodiments, the electrical connection element 210 can comprise a patterned metal sheet adjacent the first faces 110a of the LED dies 100 that is patterned to electrically connect the plurality of discrete LED dies in series and/or in parallel. Solder structures may be used to electrically connect the anode and cathode contacts 160, 170, respectively, to the patterned metal sheet. In other embodiments, the electrical connection element comprises a plurality of wire bonds adjacent the first faces 110a of the LED dies 100 that are arranged to electrically connect the plurality of discrete LED dies in series and/or in parallel.

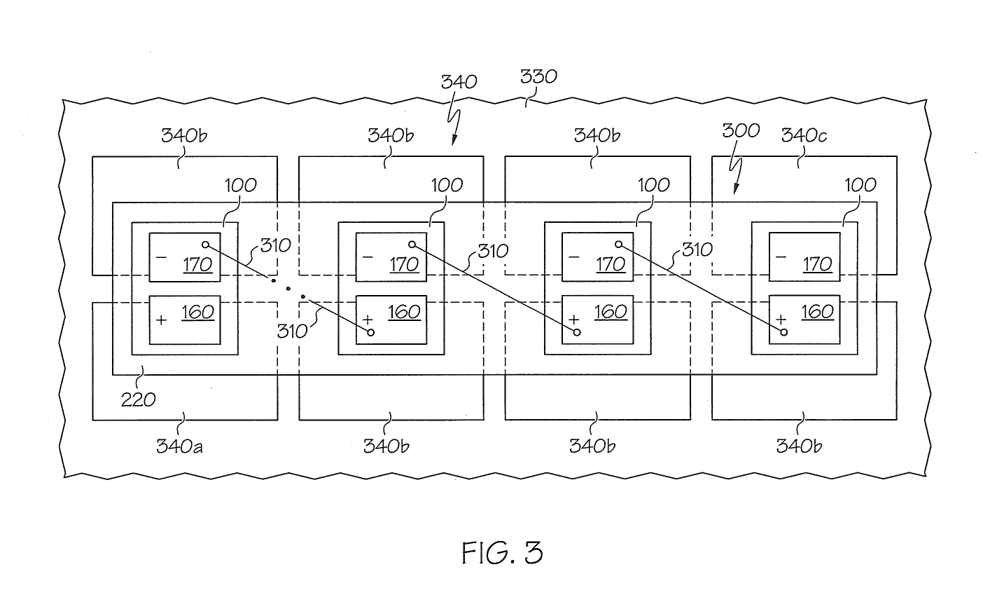

FIG. 3 is a plan view of an LED component 300 according to various embodiments described herein, wherein the electrical connection element comprises a plurality of wire bonds 310 adjacent the first faces of the LED dies 100 and arranged to electrically connect the plurality of discrete LED dies 100 in series and/or in parallel. More specifically, FIG. 3 illustrates a series connection by orienting the LED dies 100, so that anode contacts 160 of adjacent LED dies 100 are adjacent one another and cathode contacts 170 of adjacent LED dies 100 are also adjacent one another. The wire bonds 310 connect a cathode of a given LED die to an anode 160 of an adjacent LED die, so that the LED dies of FIG. 3 are connected in series. Other series connections and orientations may be provided. A high voltage LED component may thereby be provided.

Still referring to FIG. 3, a unitary optically transparent structure 220 is provided. Moreover, although not shown in FIG. 3, a layer comprising luminophoric material may be provided between the optically transparent structure 220 and the LED dies 110. As will be described below, in some embodiments, the layer comprising luminophoric material may also extend on the sidewalls 120a of the LED dies. Also, in other embodiments, an optical coupling material may be provided between the optically transparent structure 220 and the layer comprising luminophoric material.

Still referring to FIG. 3, the LED dies may be mounted on a board 330, such as a printed circuit board, multilayer printed wiring board, flexible circuit board, etc., along with other electronic components. The LED component 300 is free of a submount between the plurality of LED dies 100 and the board 330.

As also shown in FIG. 3, the board 330 may include a contact pad pattern 340 that may be provided, for example, by metal traces that are on the surface and/or internal to the board 330. The contact pad pattern 340 may include an external anode contact pad 340a, an external cathode contact pad 340c, and at least one thermal contact pad 340b for the LED component 300. A plurality of solder structures (not shown in FIG. 3) may be provided to electrically connect an anode contact 160 to the external anode contact pad 340a, a cathode contact 170 to the external cathode contact pad 340c, and an anode contact and/or a cathode contact to the thermal contact pad 340b. The solder structures may comprise solder preforms, solder bumps and/or any conventional solder structures that are used for conventional surface mount or other microelectronic fabrication technology.

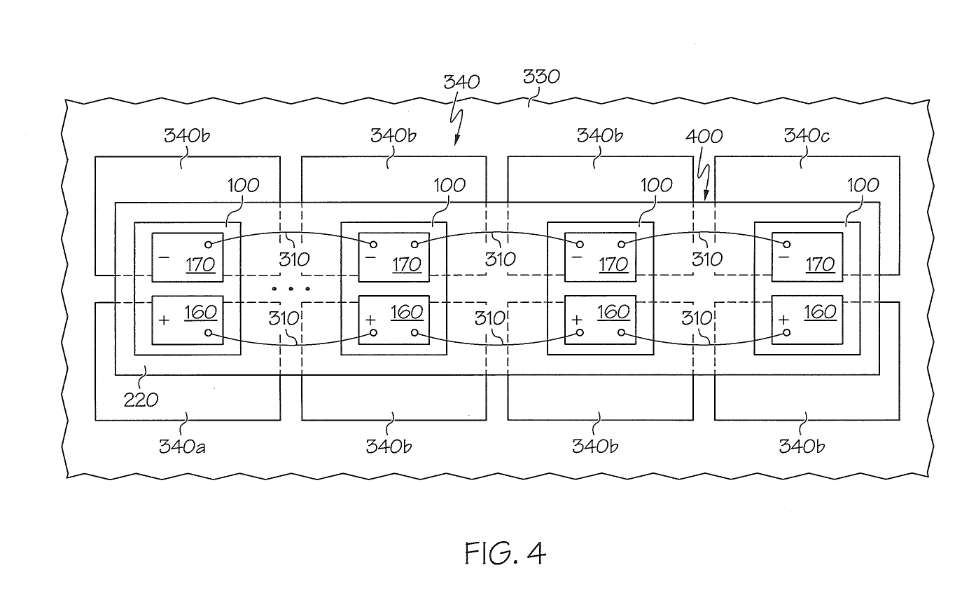

FIG. 4 is a plan view of an LED component 300 mounted on a board 330 according to various other embodiments described herein. In FIG. 4, the wire bonds 220 are arranged to electrically connect the plurality of LED dies in parallel, so as to provide a high current LED component. The wire bonds connect the LED dies in parallel by connecting the anodes 160 of adjacent LED dies 100 to one another, and by also connecting the cathodes 170 of adjacent LED dies 100 to one another. Other parallel connections and orientations may be provided.

It will also be understood that FIGS. 3 and 4 merely illustrate representative embodiments. However, in other embodiments, the LEDs may be oriented so that an anode 160 of a given LED is adjacent a cathode 170 of an adjacent LED and the anode of a given LED is opposite to the anode of the adjacent LED. Moreover, wire bond connections may also be provided to provide a combination of series and parallel LED dies.

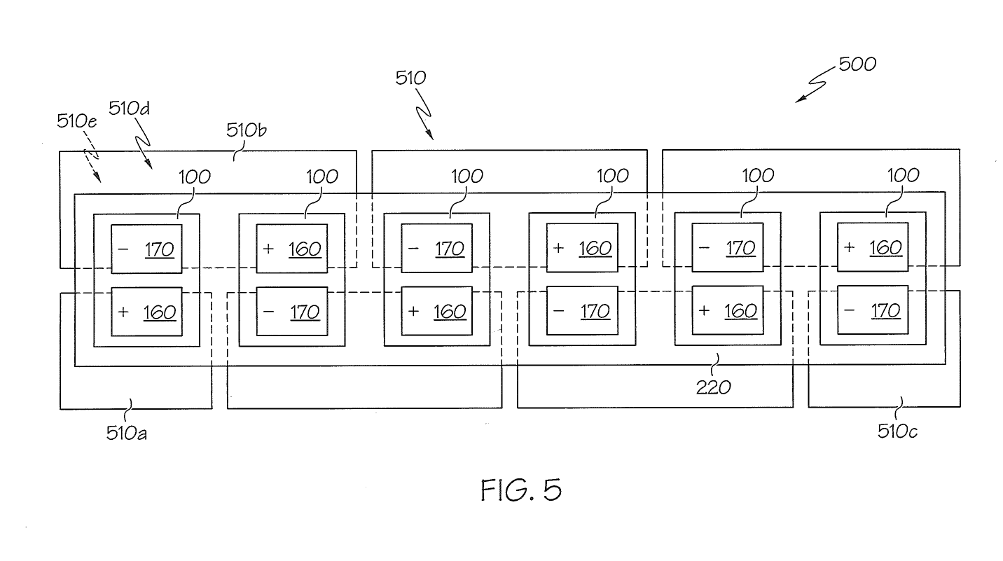

FIG. 5 is a plan view of an LED component according to various other embodiments described herein. In FIG. 5, the electrical connection element is embodied by a patterned metal sheet 510 that is adjacent the first faces of the LED dies, that is patterned to electrically connect the plurality of discrete LED dies 100 in series and/or in parallel. Thus, rather than wire bonds 310 of FIGS. 3 and 4, a patterned metal sheet 510 of FIG. 5 may be used to provide the series and/or parallel electrical connection in a submount-free LED component 500. The patterned metal sheet 510 may comprise copper and/or other metals or metal stacks that are used for microelectronic device electrodes or wiring.

In embodiments of FIG. 5, the LED dies are oriented such that anode 160 of a given LED die is adjacent a cathode 170 of an adjacent LED die. The patterned metal sheet 510 is patterned so as to electrically connect an anode of a given LED to a cathode of one adjacent LED, so as to provide a series connection of the LED dies in a component 500. The patterned metal sheet also is arranged to provide an external anode contact 510a and an external cathode contact 510c for the LED component 500. Other series connections and orientations may be provided.

As also illustrated in FIG. 5, the patterned metal sheet may comprise first and second opposing faces where the first face 510d is shown in FIG. 5 and the second face 510e is the underside of the plan view of FIG. 5, and the LED dies are disposed on the first face 510d of the patterned metal sheet, such that the anode and cathode contacts 160 and 170, respectively, are adjacent the first face of the patterned metal sheet 510d, and the second face 510e of the patterned metal sheet is free of a submount thereon adjacent the plurality of LED dies 100. A plurality of solder structures (not shown in FIG. 5) may also be provided, a respective one of which electrically connects a respective one of the anode and cathode contacts 160, 170, respectively, to the patterned metal sheet 510. An optically transparent structure 220 may also be provided, as may be a layer of luminophoric material and/or an optical coupling material. In other embodiments, one or more of these elements may be omitted. For example, the optically transparent structure 220 may be omitted. In FIG. 5, the LED component 510 is not shown mounted on a board.

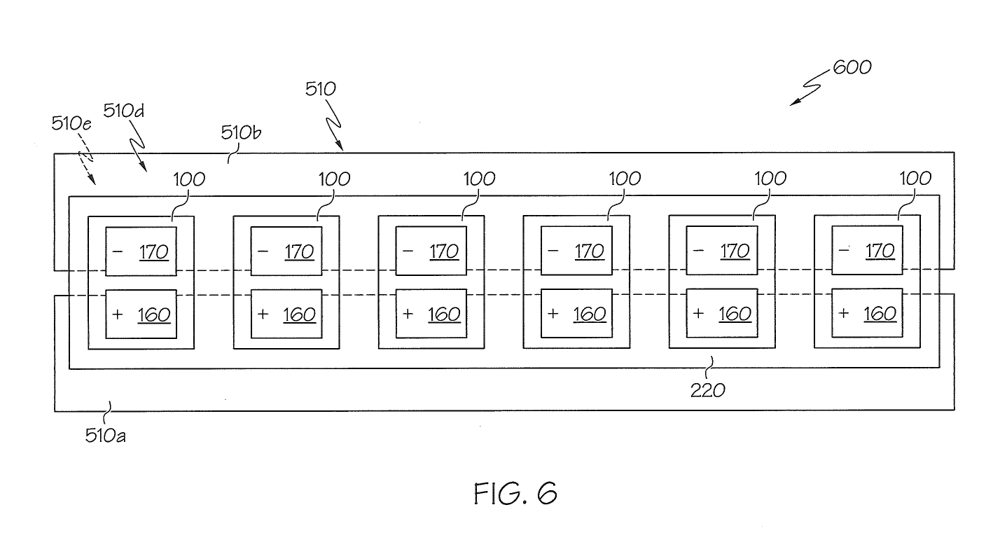

FIG. 6 is a top view of another embodiment of an LED component 600 according to various embodiments described herein. In these embodiments, LED dies are disposed on the patterned metal sheet 510, such that anode contacts 160 of adjacent LED dies 100 are adjacent one another and the cathode contacts 170 of adjacent LED dies are adjacent one another. The patterned metal sheet 510 is patterned to electrically connect the anode contacts 160 of the plurality of dies to one another and to electrically connect the cathode contacts 170 of the plurality of LED dies to one another, so that the plurality of LED dies 100 are connected in parallel. Other parallel connections and orientations may be provided. Patterned metal sheet 510 may also provide an external anode contact 510a and an external cathode contact 510b for the LED component 600. Solder structures may be used to connect the respective anode and cathode contacts 160 and 170 to the patterned metal sheet 510 on the first face 510d of the patterned metal sheet 510. The second face 510e of the patterned metal sheet that is opposite the LED dies 100 is not supported by a submount.

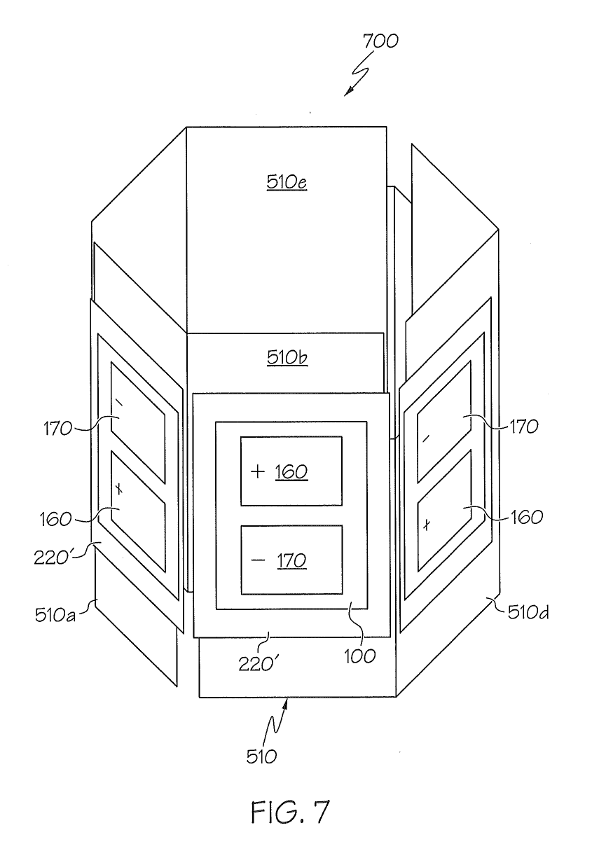

In FIGS. 2-6, the LED components all are illustrated as being planar. However, nonplanar LED components may also be provided according to various embodiments described herein, as illustrated, for example, in FIG. 7. FIG. 7 corresponds to embodiments of FIG. 5, wherein the patterned metal sheet 510 is bent (for example into a hexagonal shape), to thereby provide a freestanding LED component that may radiate light in a 360° omnidirectional manner. Embodiments of FIG. 7 may be particularly useful as a replacement or a filament of an incandescent light bulb. In these embodiments, the patterned metal sheet 510 may also function as a heat dissipation structure and as a support mechanism for the LED component. It will also be understood that, in embodiments of FIG. 7, the optically transparent structure 220′ is not a unitary optically transparent structure, such as a single glass sheet that spans the LED dies 100. Rather, a discrete optically transparent structure 220′, such as a discrete rigid sheet, for example a glass sheet, is provided on a respective LED die 100 remote from the anode and cathode contacts 160 and 170.

In general, embodiments of FIG. 7 may configure the patterned metal sheet 510 as a polygonal cylinder having a plurality of polygonal cylinder faces, wherein at least one of the respective LED dies 110 is on a respective polygonal cylinder face and wherein the patterned metal sheet 510 connects adjacent polygonal cylinder faces to one another. An edge of the patterned metal sheet 510, such as the bottom edge of FIG. 7, may be mounted on a board, so that the axis of the polygonal cylinder is orthogonal to the board. The anode contact 510a and/or the cathode contact 510b (not shown in FIG. 7) may be elongated to provide a mounting surface to a mounting board, so that the remainder of the polygonal cylinder is not directly on a board of a mounting support. It will be understood that embodiments of FIGS. 2-6 may also be configured into a polygonal cylinder and/or other open or closed polygonal shapes, depending on the requirements of the LED component application. Note that the faces need not be equal size, the angles between the faces need not be equal, the bends need not be discrete bends, but, rather, may be curved portions of the polygonal metal sheet, and/or some faces of the polygonal metal sheet may include more than one LED die or may not include any LED dies.

Moreover, polyhedral LED components may also be provided in other embodiments, depending on the number and orientation of the LED dies and the configuration of the patterned metal sheet. Polygonal or polyhedral wire bonded LED components may also be provided in other embodiments.

FIG. 8 is a cross-sectional view of an LED component 800 according to various embodiments described herein. The LED component 800 uses wire bonds 310 to connect a plurality of LED dies 100 in series analogous to that which was illustrated in FIG. 3.

More specifically, referring to FIG. 8, a plurality of discrete LED dies 100 are spaced apart from one another. A respective LED 100 comprises first 110a and second 120b opposing faces, and an anode contact 160 and a cathode contact 170 on the first face 110a thereof. The plurality of discrete LED dies 100 are oriented such that the first faces 110a of the adjacent LED dies 100 are adjacent one another, and the second faces 120b of adjacent LED dies 100 are adjacent one another. The LED component 800 is not supported by a submount adjacent the first faces 110a of the LED dies 100 that span the first faces 110a of adjacent ones of the LED dies 100. A plurality of wire bonds 310 are provided adjacent the first faces 100a of the LED dies that are configured to electrically connect the plurality of discrete LED dies in series and/or in parallel (in series in FIG. 8).

Continuing with the description of FIG. 8, a plurality of solder structures 810 are also provided, a respective one of which is on a respective one of the anode and cathode contacts 160, 170, respectively. The solder structures may be preforms, solder bumps, solder balls and/or any other solder structure that is used in microelectronic technology. More specifically, the solder structures may comprise eutectic gold/tin solder, tin solder bump, solder paste and/or solder preform form, and may also include other solder compositions, such as lead/tin solders, tin/silver/copper solders, known as “SAC” solder and/or other solder configurations. It will be understood that a solder structure 810 need not be provided on each anode contact 160 or cathode contact 170. A layer 820 comprising luminophoric material, such as phosphor, is also provided on the second faces 120b of the LED dies 100, wherein the layer 820 comprising luminophoric material also extends on sidewalls 120a of the LED dies 100.

A unitary optically transparent structure 220 is provided on the layer 820 comprising luminophoric material, remote from the LED dies 100. The unitary optically transparent structure 220 spans the plurality of LED dies. The unitary optically transparent structure 220 may comprise a sheet, such as a rigid sheet, for example a glass sheet. In some embodiments, the unitary optically transparent structure 220 may be directly on the portion of the layer 820 comprising luminophoric material that is on the second face 120b of the LED dies 100. In other embodiments, the unitary optically transparent structure 220 may be spaced apart therefrom. In some embodiments, the unitary optically transparent structure 220 provides mechanical support for the LED component 800. An optical coupling material 830, such as a gel or resin, for example comprising silicone, may be provided between the optically transparent structure 220 and the layer 820 comprising luminophoric material. The optical coupling material 830 may also include luminophoric material therein. Finally, a reflective layer 840 may be provided on the first faces 110a of the LED dies 100, and extending between adjacent ones of the LED dies 100. The reflective layer 840 may comprise white paint and/or other solder mask material, in some embodiments. In some embodiments, although not illustrated in FIG. 8, the reflective layer 840 may also extend partially onto the sidewalls 120a of the LED dies 100, adjacent the first faces 110a thereof. More specifically, when the die 100 is pressed onto a tape, as will be described in detail below, the die may sink slightly into the tape. Thus, when the tape is removed in later steps, a small part of the die sidewall faces may be exposed during the white paint process.

It will be understood that the solder structures 810, the layer 820 comprising luminophoric material, the optical coupling material 830, the unitary optically transparent structure 220 and/or the reflective layer 840 may be used in various combinations and subcombinations. For example, the layer 820 comprising luminophoric material may be omitted and, instead, luminophoric material may be provided in the optical coupling material. Alternatively, the optical coupling material may be omitted, and the unitary transparent structure 220 may include luminophoric material therein. In other embodiments, the optical coupling media may contain luminophoric material therein. In yet other embodiments, luminophoric material may be included in each of the layer 820, the coupling media 830 and the optically transparent structure 220, wherein the luminophoric materials may be different in at least two of the layers. The luminophoric material may be uniformly or non-uniformly distributed in a given layer, and multiple luminophoric materials may be provided in a given layer. In still other embodiments, the optically transparent structure 220 may be a flexible unitary optically transparent structure comprising, for example, silicone that may extend on the second faces 120b and at least partially on the sidewalls 120a of the LED dies 100. A separate layer of optical coupling material 830 may or may not be provided. Finally, it will be understood that the LED dies 100 may be disposed, such that the anode contacts 160 of adjacent LED dies are adjacent one another, and the cathode contacts 170 of adjacent LED dies 100 are adjacent one another, and the wire bonds 310 may be configured to electrically connect the anode contacts 160 of the plurality of LED dies to one another, and to electrically connect the cathode contacts 170 of the plurality of LED dies to one another, so that the plurality of LED dies are connected in parallel.

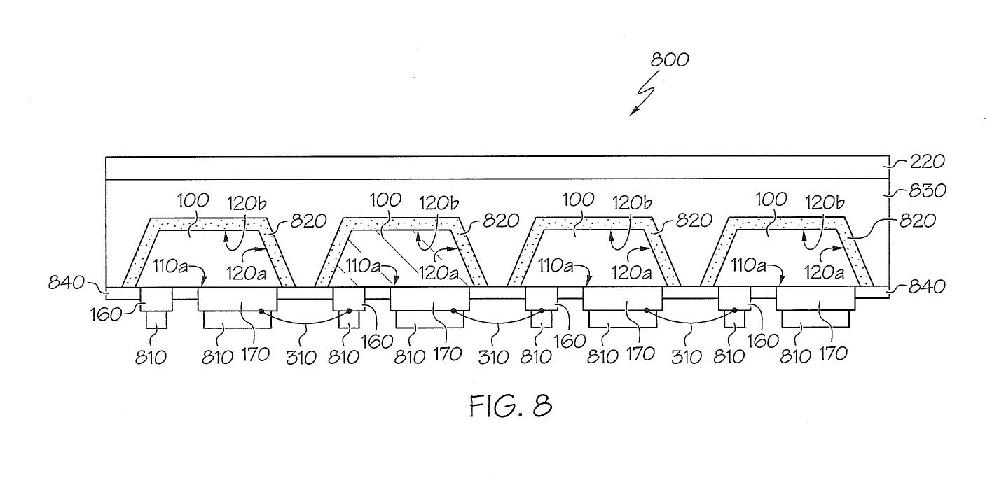

FIG. 9 illustrates other embodiments, wherein an LED component 800 of FIG. 8 is mounted on a board 330, along with other electronic components 910, wherein the LED component 800 is free of a submount between a plurality of LED dies 100 and the board 330. As also illustrated, the board comprises a contact pad pattern including an external anode contact pad 340a for the LED component 800, an external cathode contact pad 340c for the LED component and at least one thermal contact pad 340b for the LED component. Solder structures 810 electrically connect an anode contact 160 to the external anode contact pad 340a, a cathode contact 170 to the external cathode contact pad 340c, and an anode contact and/or a cathode contact to the thermal contact pad 340b.

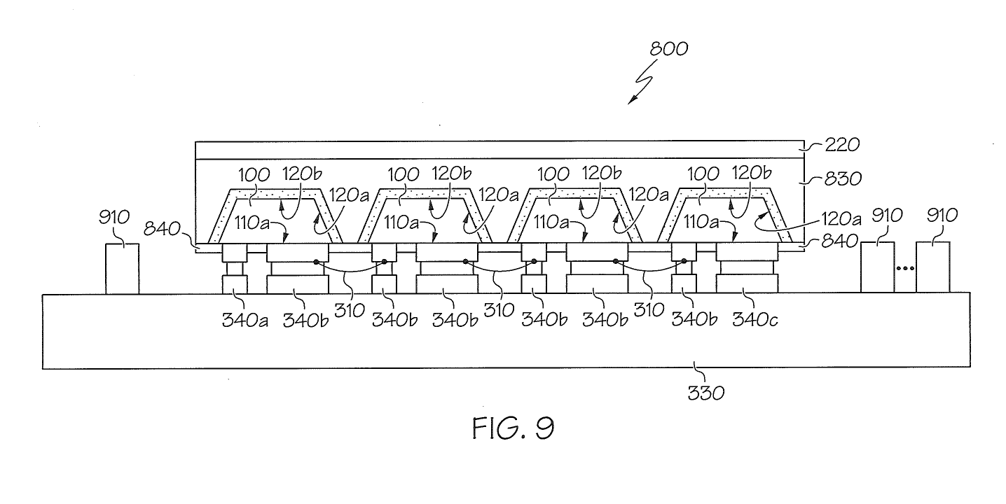

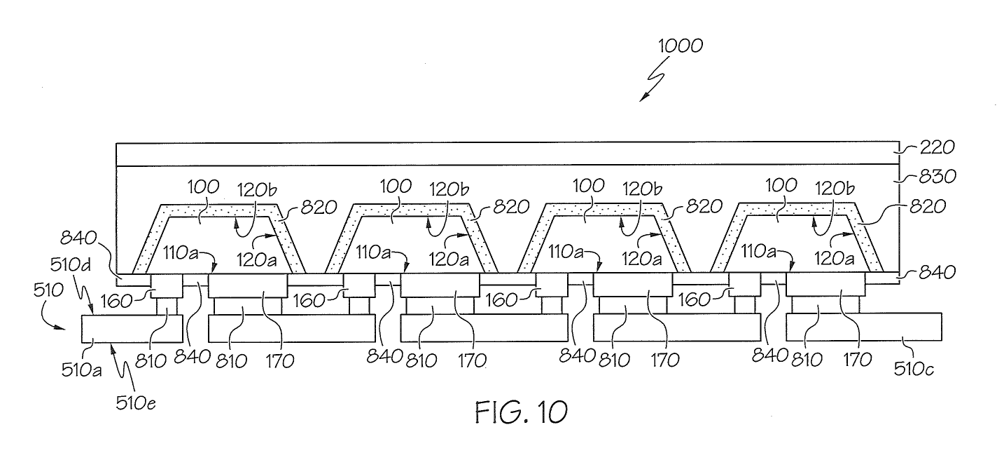

FIG. 10 is a cross-sectional view of an LED component according to various other embodiments described herein, which may correspond to an LED component that was illustrated in plan view of FIG. 5. FIG. 10 illustrates a light emitting diode component 1000 that comprises a plurality of discrete LED dies 100 that are spaced apart from one another, a respective one of which comprises first 110a and second 120b opposing faces, and an anode contact 160 and cathode contact 170 on the first face 110a thereof. The plurality of discrete LED dies are oriented such that the first faces 110a of the adjacent LED dies 100 are adjacent one another, and the second faces 120b of the LED dies are adjacent one another. The LED component 1000 is unsupported by a submount adjacent the first faces 110a of the LED dies 100 that spans the first faces of adjacent ones of the LED dies 100.

Still referring to FIG. 10, a patterned metal sheet 510 comprising first 510d and second 510e opposing faces is also provided. The LED dies 100 are disposed on the first face 510d of the patterned metal sheet 510, such that the anode and cathode contacts 160 and 170 are adjacent the first face 510d of the patterned metal sheet and the second face 510e of the patterned metal sheet 510 is free of a submount thereon adjacent the plurality of LED dies 100. A plurality of solder structures 810 are also provided, a respective one of which electrically connects a respective one of the anode and cathode contacts 160 and 170, respectively, to the patterned metal sheet 510. The patterned metal sheet 510 is patterned to selectively electrically connect the anode and cathode contacts 160 and 170 of the LED dies in series and/or in parallel (a series connection is illustrated in FIG. 10) through the solder structures 810, and to also provide an external anode contact 510a and an external cathode contact 510c for the LED component. A layer comprising luminophoric material 820, an optically transparent structure 220, an optical coupling material 830 and/or a reflective layer 840 is also provided, as was described in connection with FIGS. 8 and 9.

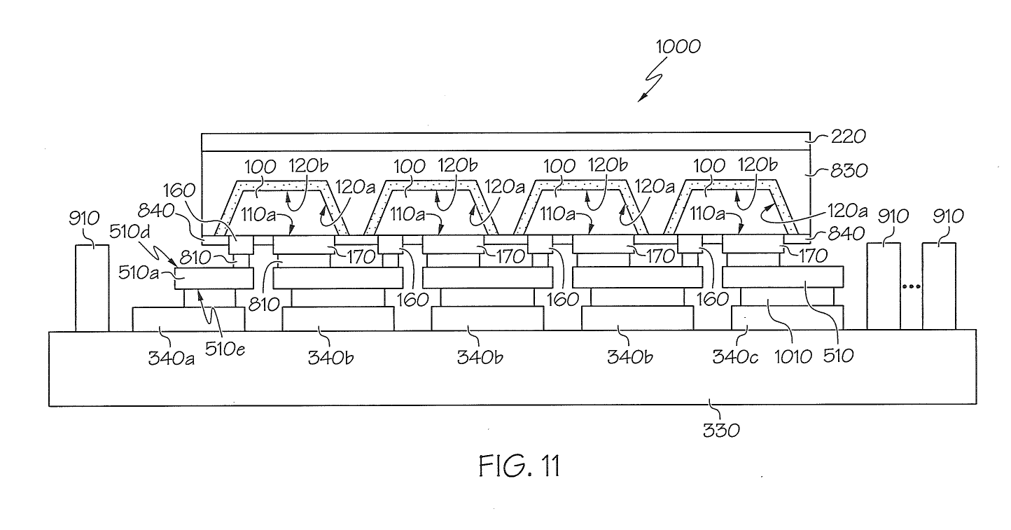

FIG. 11 illustrates an LED component 1000 of FIG. 10 mounted on a board 330, along with other electronic components 910, wherein the LED component 1000 is free of a submount between the plurality of LED dies 100 and the board 330. The board 330 may also provide an anode pad 340a, a cathode pad 340c and/or one or more thermal pads 340b that are connected to the respective portions of the patterned metal sheet 510 by a second solder structure 1010.

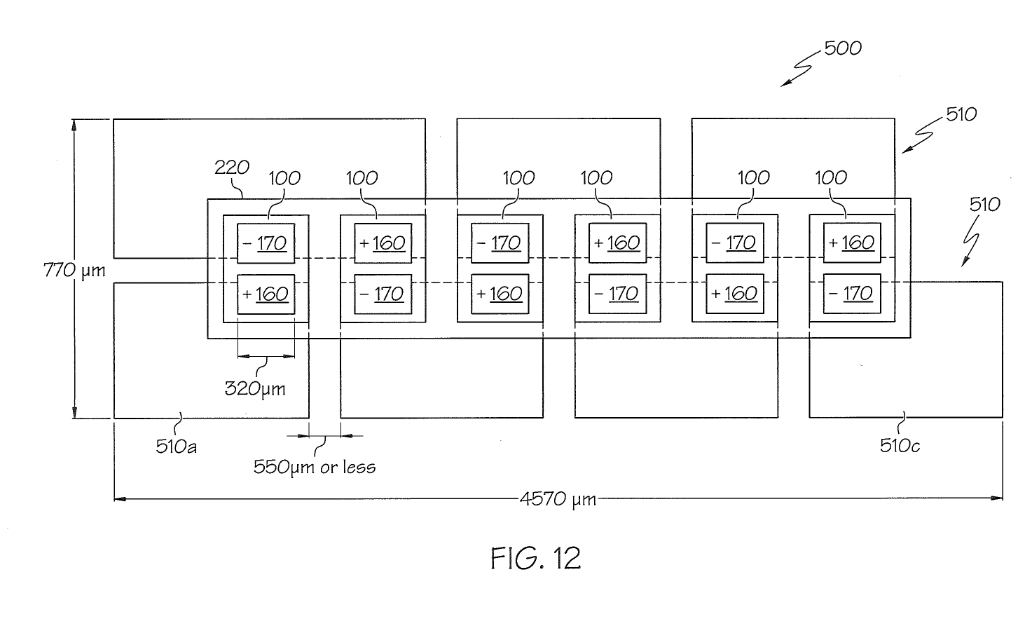

FIG. 12 is a top view of an LED component corresponding to FIG. 5, with dimensions of various embodiments included. In these embodiments, six square LED die of dimension 320 μm×320 μm were used in a linear array, to provide a 18 volt device by series connection. As shown, the dimensions of the patterned metal sheet 510, which corresponds to the overall footprint of the LED component 500, is about 770 μm×4570 μm. It will be understood that the LED die need not be oriented in a linear array. Rather, square or rectangular components may also be provided, as may a curved component. In other embodiments, 100 μm×100 μm LED dies may be used and mounted on a 1″×1″ board.

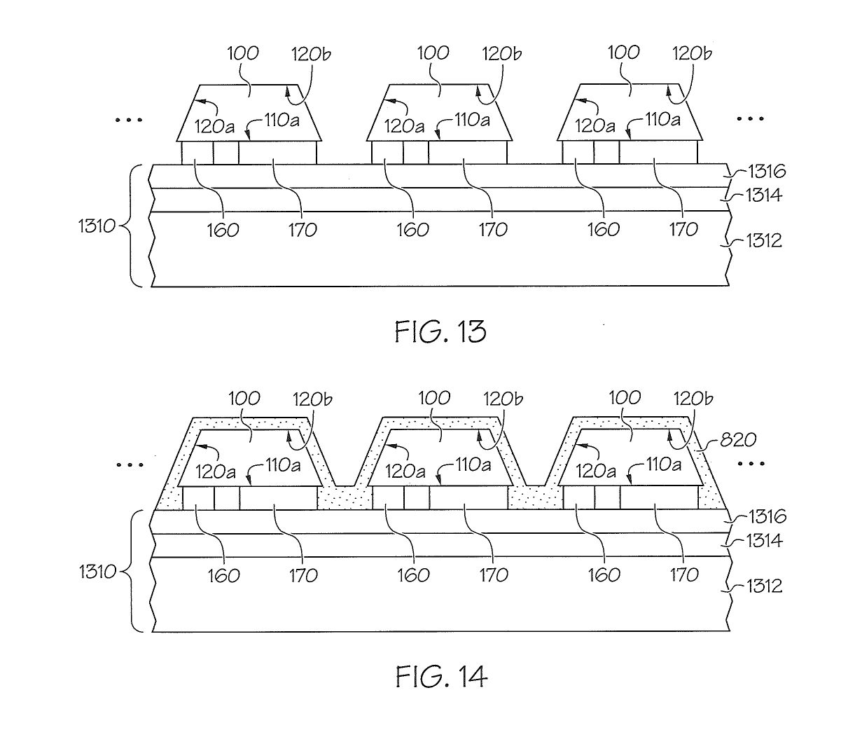

FIGS. 13-20 are cross-sectional views of intermediate and final LED component structures according to various embodiments described herein, to illustrate methods of fabricating an LED component according to various embodiments described herein. More specifically, FIGS. 13-20 illustrate fabricating an LED component 800 of FIG. 8 according to various embodiments described herein. Referring to FIG. 13, a plurality of LED dies 100 are fabricated, for example in a semiconductor wafer, and are then singulated, binned and sorted. A group of binned and sorted discrete LED dies 100 are placed on a carrier sheet 1310 in spaced apart relation from one another. A respective LED die 100 comprises first and second opposing faces 110a and 120b, respectively, and an anode contact 160 and a cathode contact 170 on the first face thereof. The plurality of discrete LED dies 100 are oriented on the carrier sheet 1310, such that the first faces 1100a of adjacent LED dies 100 are adjacent the carrier sheet 1310, and the second faces 120b of adjacent LED dies 110 are remote from the carrier sheet 1310. In some embodiments, the carrier sheet 1310 may be embodied as a multilayer carrier sheet, including a bottom rigid layer 1312, a Thermal Release (TR) intermediate layer 1314 and a top ultraviolet curable layer 1316.

Referring now to FIG. 14, a conformal luminophoric layer 820 is coated on the second faces 120b and sidewalls 120a of the LED dies 100, for example using spray coating.

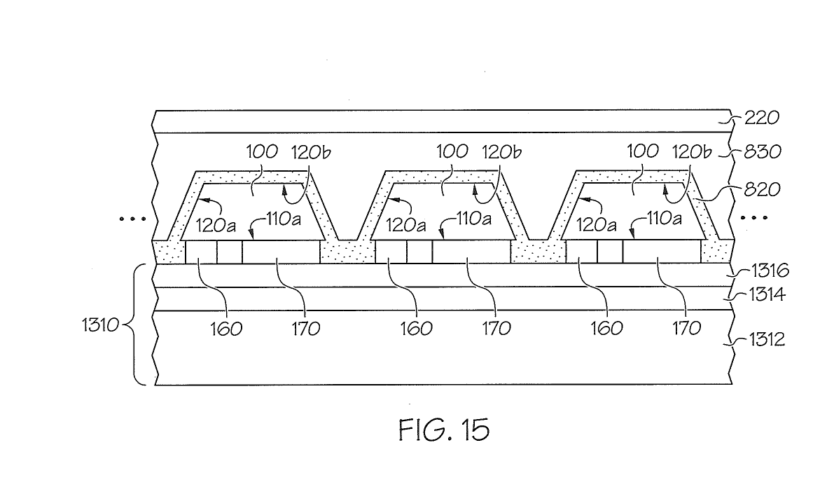

Referring to FIG. 15, a unitary optically transparent structure, such as a glass sheet 220, is placed on the second faces 120b of the LED dies 100, so that the unitary optically transparent structure 220 spans the LED dies 100. In some embodiments, an optical coupling material 830, such as clear silicone, may be dispensed on the LED dies 100 prior to placing the glass sheet 220 thereon. In other embodiments, the optical coupling material 220 may be provided after the glass sheet, or may not be provided at all.

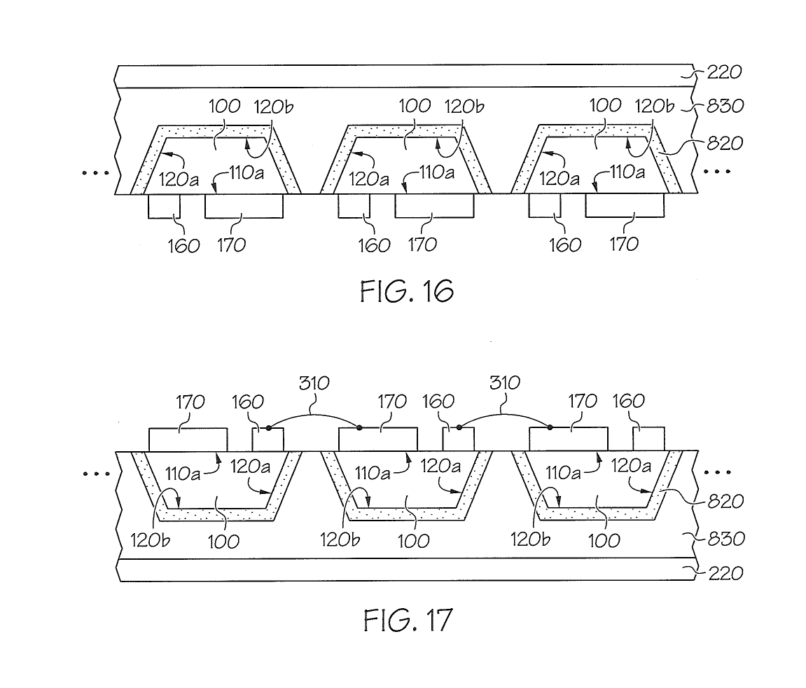

Referring now to FIG. 16, the carrier sheet 1310 is removed, for example by dissolving the Thermal Release (TR) tape 1314, such that the unitary optical transparent structure 220 and/or the optical coupling media 830 supports the plurality of discrete LED dies 100 thereon. The ultraviolet curable layer 1316 may also be removed.

Referring to FIG. 17, the plurality of discrete LED dies that are on the unitary optically transparent structure 220 are then connected in series and/or in parallel by wire bonding 310 selected anode and cathode contacts 160 and 170, respectively, to one another. In FIG. 17, a series connection is shown.

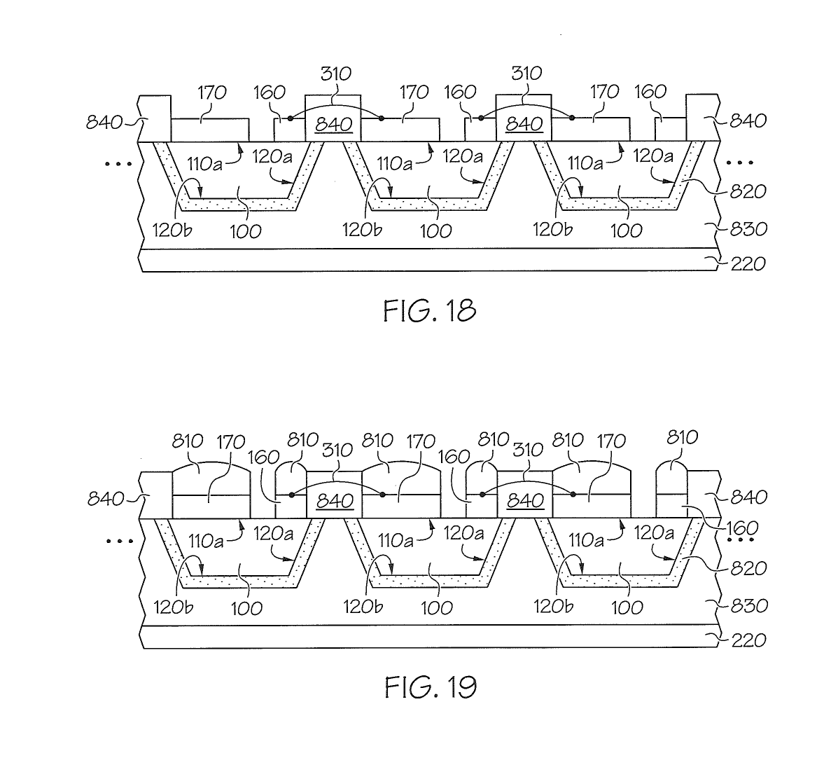

Referring to FIG. 18, a reflective layer 840, such as white paint, is applied on the first face 1110a of the LED dies and extending between adjacent ones of the LED dies 100. The white paint may be applied, for example by screen-printing. In some embodiments, although not illustrated in FIG. 18, the reflective layer 840 may also extend partially onto the sidewalls 120a of the LED dies 100, adjacent the first faces 110a thereof. More specifically, when the die is pressed onto the carrier sheet or tape 1310, the die may sink slightly into the tape 1310. Thus, when the tape 1310 is removed in later steps, a small part of the die sidewall faces may be exposed during the white paint process.

Referring now to FIG. 19, solder paste may be stenciled on the anode and cathode contact pads 160 and 170, and then may be reflowed. As shown in FIG. 19, in some embodiments, the reflective layer 840 and the solder layer 810 may be sufficiently thick, such that the wire bonds 310 are buried in the reflective layer 840 and the solder layer 810 to provide additional support for the wire bonds 310. For example, in some embodiments, the reflective layer 840 may be about 40 μm thick and the solder layer 810 may be about 50 μm thick. It will be understood that the order of application between the white paint (FIG. 18) and the solder paste (FIG. 19) can be interchanged such that the solder paste is applied and reflowed prior to applying the white paint.

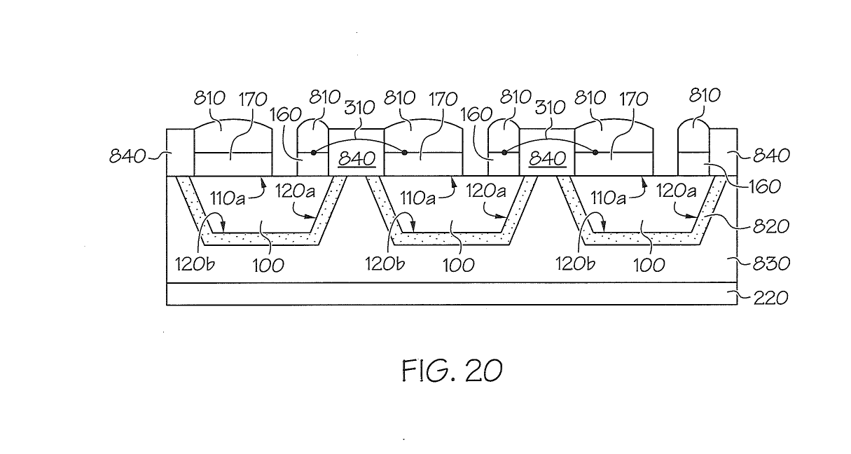

Finally, referring to FIG. 20, groups of the LED dies that are connected in series and/or parallel are singulated, to provide a plurality of the LED components, a respective LED component being unsupported by the submount adjacent the first faces of the LED die that spans the first faces of adjacent ones of the LED dies. Singulating may be a multistep process, which can include scribing and sawing in some embodiments. An LED component, as illustrated in FIG. 20, may then be mounted on a board, as was illustrated in FIG. 9.

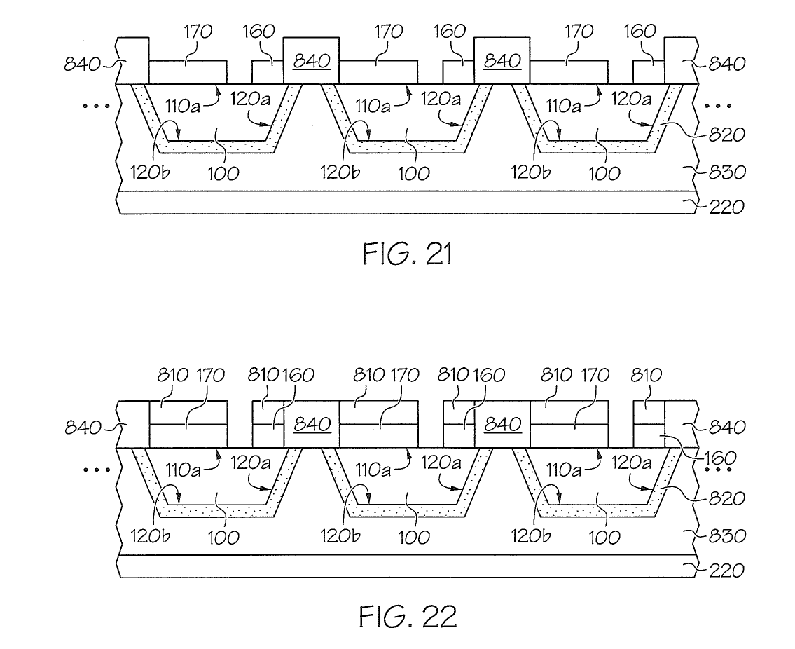

Methods of fabricating an LED component according to various other embodiments described herein will now be described. These methods may fabricate LED components 1000 of FIG. 10. More specifically, in these embodiments, the operations of FIGS. 13-16 may first be performed. Then, referring to FIG. 21, a reflective layer 840 is applied to the first faces 110a of the LED dies 100 and extending between adjacent ones of the LED dies, as was described in connection with FIG. 18. The reflective layer 840 may also function as a solder mask.

Referring to FIG. 22, a solder structure 810 is placed on a respective anode contact 160 and cathode contact 170, as was described, for example, in connection with FIG. 20. The solder structures 810 need not be reflowed.

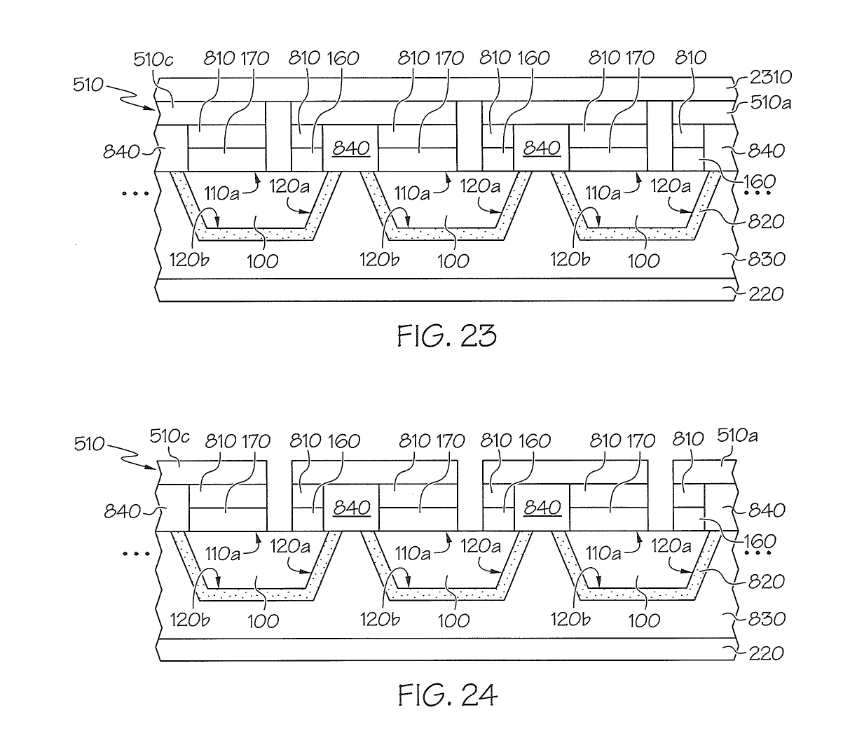

Referring to FIG. 23, a patterned metal sheet 510 is fabricated on a carrier sheet 2310. The carrier sheet may be similar to the carrier sheet 1310 of FIG. 13 in some embodiments. In other embodiments, a flexible carrier sheet may be provided. The patterned metal sheet 510 may be fabricated on the carrier sheet 2310 by forming or placing a blanket metal sheet on the carrier sheet, and then selectively etching the blanket metal sheet to provide a patterned carrier sheet. In other embodiments, discrete pieces of the patterned metal sheet 510 may be placed in spaced apart relation on the carrier sheet 2310. In still other embodiments, a carrier sheet need not be used, but rather the segments of the patterned metal sheet 510 may be placed directly on the solder structures 810, as shown in FIG. 23.

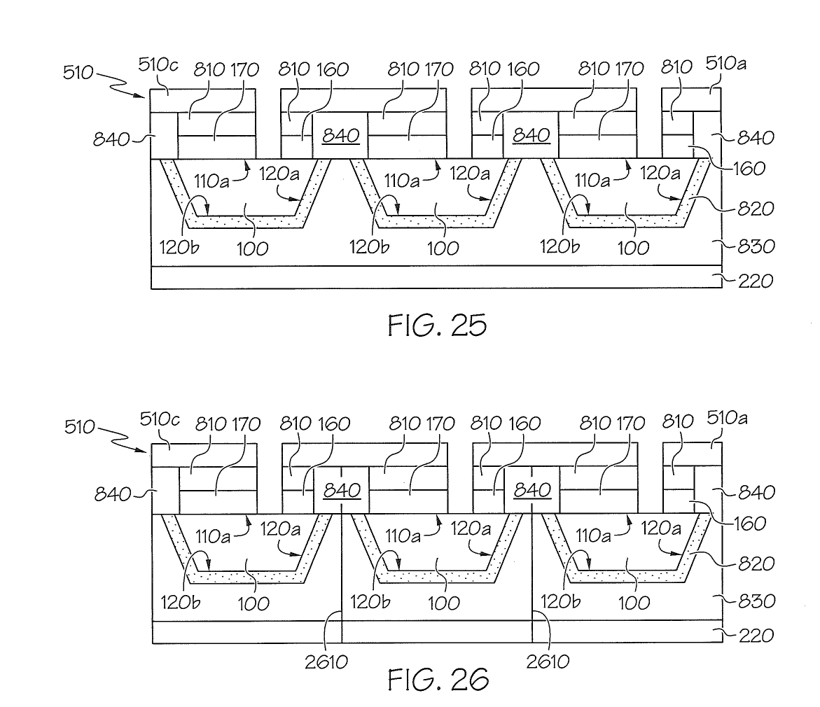

Referring now to FIG. 24, the carrier sheet 2310 is removed if present. Referring to FIG. 25, the individual components are singulated as was described in connection with FIG. 20, to provide the LED component 1000 of FIG. 10. The component may be mounted on a board, as was illustrated in FIG. 11. Finally, as illustrated in FIG. 26, the optically transparent sheet 220, optical coupling material 830 and the reflective layer 840 may be cut as illustrated by lines 2610, and the patterned metal sheet 510 may be bent, to provide a polygonal cylinder as was illustrated, for example, in FIG. 7. Wire bond embodiments may also be bent into a polygonal cylinder. Polyhedral LED components may also be provided.

Additional discussion of LED components according to various embodiments described herein will now be provided.

Specifically, various embodiments described herein can allow the use of multiple small dies with spacing, which can be advantageous over larger dies in light output due to less self-absorption by the LED dies. Small dies may also be less costly than larger dies, due to higher die-per-wafer yield. The tradeoff may be more placements and interconnects, but these may be almost free with modern manufacturing techniques. Multiple small dies can be used in low voltage applications, or can be structured together to form higher voltage components. Multiple small dies may be used to form one component without a submount. This can provide increased area for better thermal dissipation compared to a single die solution, which can provide less thermal roll-off of luminous flux. Specifically, thermal management may be better as heat sources may be distributed rather than being concentrated or crowded. Moreover, thermal management may be better as connecting substrate pads may be made larger with better heat conduction possible. Finally, an increase in luminous flux may be provided due to less self-absorption compared to a single die.

In other embodiments, a single multi-die component may be used for multiple voltages or staged turn-on within a component. Moreover, since no submount is required, cost and/or reliability may be increased. The increase in die perimeter area compared to a single die can correlate to efficiency gain. It will also be understood that various embodiments described herein may require more accurate placement of a component on a board, because the component may be larger. Moreover, handling this larger component may be mitigated using existing multiple ejector pin arrangements that can eject a large component from a carrier sheet.

Various embodiments described herein can utilize a reflective layer. These reflective layers can include a dielectric mirror, a white paint reflective layer, such as a titania-filled layer, and/or other white/reflective layer. Many different reflectors can be used including a mirror layer comprising silver, diffuse reflectors, materials comprising a reflective white color, and thin film reflectors, such as metal or dielectric layers. The reflective layer may have various thicknesses, including some which do not exceed the thickness of the anode and cathode contacts. The reflective layer shown may also extend between the anode and cathode contacts. In embodiments where the reflective layer exceeds the height of the anode and cathode contacts, it may be desirable to generate a contact with enough material to overcome the height barrier of the reflective layer and also to have a balanced amount of material on both contact pads so that uniform attachment is achieved.

Some embodiments of the reflective layer may also comprise a solder mask over portions of the bottom surface, which do not include the anode and cathode contacts. A solder mask may comprise any material that is generally used in microelectronic manufacturing to physically and electrically insulate those portions of the circuit to which no solder or soldering is desired. Solder masks may include thermally cured screen-printed masks, dry film and/or screen-applied or curtain-coated liquid photoimageable solder masks. In some embodiments, the solder mask may comprise a conventional photoresist, or any other material that is non-wettable to solder. A solder mask may be less than about 30 μm thick in some embodiments, less than about 5 μm thick in other embodiments, and may be about 1 μm thick or less in still other embodiments. A wide range of thicknesses and materials may be used, as long as effective solder masking takes place. Moreover, in other embodiments, the solder mask may also include virtually any non-metallic coating, such as silicon dioxide and/or silicon nitride, which may be deposited by physical and/or chemical deposition techniques. In still other embodiments, the solder mask may be reflective, so as to reflect optical radiation that emerges from the diode region, back into the diode region. Examples of such reflective layers include a dielectric mirror, a white reflective layer, such as a titania-filled layer, and/or other white/reflective layer.

Various embodiments described herein may also include a layer comprising luminophoric material, also referred to as a phosphor layer. The phosphor layer may also extend onto the sidewalls of the diode dies, and/or beyond the anode and cathode contacts. In some embodiments, the phosphor layer is a conformal phosphor layer that may be less than about 150 μm thick in some embodiments, less than about 100 μm thick in other embodiments and less than about 50 μm thick in yet other embodiments. It will be understood that the term “phosphor” is used herein to denote any wavelength conversion material, and may be provided according to various configurations. The phosphor layer may also be any type of functional layer or layers, such as any layer disposed to affect the properties of the emitted light, for example, color, intensity and/or direction.

Various techniques may be used to apply the phosphor layer, including dispensing, screen printing, film transfer, spraying, coating and/or other techniques. Phosphor preforms also may be applied. In some embodiments, the phosphor layer may comprise silicone and/or other transparent material having phosphor particles therein. It will also be understood that the phosphor layer may be coplanar with the outer face of the LED dies. However, the outer or edge portions of the phosphor layer need not be co-planar with these outer faces. Specifically, it can be recessed from the outer faces or may protrude beyond the anode and cathode contacts.

The phosphor layer may be a thin conformal layer having uniform phosphor particle density. However, a phosphor layer may be provided that comprises phosphor particles that are nonuniformly dispersed therein, and that, in some embodiments, may include a phosphor-free region at the exterior surfaces of the phosphor layer. Moreover, the phosphor layer may also be configured as a conformal layer.

The phosphor layer, or any wavelength conversion layer, converts a portion of the light emitted from the LED die to a different wavelength, a process that is known in the art. One example of this process, is converting a portion of blue-emitted light from light emitter, such as an LED die, to yellow light. Yttrium aluminum garnet (YAG) is an example of a common phosphor that may be used.

In some embodiments, the phosphor particles comprise many different compositions and phosphor materials alone or in combination. In one embodiment the single crystalline phosphor can comprise yttrium aluminum garnet (YAG, with chemical formula Y₃Al₅O₁₂). The YAG host can be combined with other compounds to achieve the desired emission wavelength. In one embodiment where the single crystalline phosphor absorbs blue light and reemits yellow, the single crystalline phosphor can comprise YAG:Ce. This embodiment is particularly applicable to light emitters that emit a white light combination of blue and yellow light. A full range of broad yellow spectral emission is possible using conversion particles made of phosphors based on the (Gd,Y)₃(Al,Ga)₅O₁₂:Ce system, which include Y₃Al₅O₁₂:Ce (YAG). Other yellow phosphors that can be used for white emitting LED chips include:
Tb₃₋ₓReₓO₁₂:Ce (TAG);
RE=Y, Gd, La, Lu; and/or
Sr_{2-x-y}BaₓCa_{y}SiO₄:Eu.

In other embodiments, other compounds can be used with a YAG host for absorption and re-emission of different wavelengths of light. For example, a YAG:Nb single crystal phosphor can be provided to absorb blue light and reemit red light. First and second phosphors can also be combined for higher CRI white (i.e., warm white) with the yellow phosphors above combined with red phosphors. Various red phosphors can be used including:
SrₓCa₁₋ₓS:Eu,Y; Y=halide;
CaSiAlN₃:Eu; or
Sr_{2-y}Ca_{y}SiO₄:Eu.

Other phosphors can be used to create saturated color emission by converting substantially all light to a particular color. For example, the following phosphors can be used to generate great saturated light:
SrGa₂S₄:Eu;
Sr_{2-y}Ba_{y}SiO₄:Eu; or
SrSi₂O₂N₂:Eu.

The following lists some additional suitable phosphors that can be used as conversion particles, although others can be used. Each exhibits excitation in the blue and/or UV emission spectrum, provides a desirable peak emission, has efficient light conversion:
YELLOW/GREEN
(Sr,Ca,Ba)(Al,Ga)₂S₄:Eu²⁺
Ba₂(Mg,Zn)Si₂O₇ Eu²⁺
Gd_{0.46}Sr_{0.31}Al_{1.23}OₓF_{1.38}: Eu²⁺_{0.6}
(Ba_{1-x-y}SrₓCa_{y})SiO₄:Eu
Ba₂SiO₄=Eu²⁺
RED
Lu₂O₃=Eu³⁺
(Sr₂₋ₓLaₓ)(Cei_{—x}Euₓ)O₄
Sr₂C₁₋ₓEuₓO₄
SrTiO₃:Pr³⁺, GA³⁺
CaAlSiN₃IEu²⁺
Sr₂Si₅N₈=Eu²⁺

In some embodiments, the layer comprising luminophoric material, the optical coupling layer and/or the optically transparent structure may also provide a functional layer which comprises a light scattering layer, which comprises a binder material as discussed above and light scattering particles, for example titanium oxide particles. In other embodiments, the layer comprises materials to alter the refractive index of the functional layer. In some embodiments, the functional layer comprises a combination of one or more of the types of functional layers described herein (e.g. a wavelength conversion layer and a scattering or refractive index altering layer).

In some embodiments, the LED die is configured to emit blue light, for example light having a dominant wavelength of about 450-460 nm, and the phosphor layer comprises yellow phosphor, such as YAG:Ce phosphor, having a peak wavelength of about 550 nm. In other embodiments, the LED die is configured to emit blue light upon energization thereof, and the phosphor layer may comprise a mixture of yellow phosphor and red phosphor, such CASN-based phosphor. In still other embodiments, the LED die is configured to emit blue light upon energization thereof, and the phosphor layer may comprise a mixture of yellow phosphor, red phosphor and green phosphor, such as LuAG: Ce phosphor particles. Moreover, various combinations and subcombinations of these and/or other colors and/or types of phosphors may be used in mixtures and/or in separate layers. In still other embodiments, a phosphor layer is not used. For example, a blue, green, amber, red, etc., LED need not use phosphor. In embodiments which do use a phosphor, it may be beneficial to provide a uniform coating in order to provide more uniform emissions.

The optical coupling material may comprise silicone without phosphor particles therein, and may provide a primary optic for the light emitting device. The optical coupling material that is free of phosphor may be shaped to provide a lens, dome and/or other optical component, so that the sides and/or tops thereof may be oblique to the diode region. The optical coupling material that is free of phosphor may also encapsulate the phosphor layer and/or light emitting surfaces of the LED die. The optical coupling layer may be at least 1.5 mm thick in some embodiments, at least 0.5 mm thick in other embodiments, and at least 0.01 mm thick in yet other embodiments, and may not be present in still other embodiments. Thus, in other embodiments, an optical coupling material layer may be used without a phosphor layer. For example, the optical coupling material may be directly on the second face of the LED die. In some embodiments, a relatively thick transparent layer may be used. In other embodiments, a conformal transparent layer may be used. In still other embodiments, the transparent layer may be provided on a phosphor layer that comprises phosphor particles that are non-uniformly dispersed therein. The device may further include an additional encapsulant or lens, which may be silicone or glass. Other embodiments may not include this additional lens.

Various embodiments described herein may also include a board, such as a printed circuit board. The printed circuit board may include any conventional circuit board material that is used to mechanically support and electrically connect electronic components using conductive pathways, tracks or signal traces. The printed circuit board may comprise laminate, copper-clad laminates, resin-impregnated B-stage cloth, copper foil, metal clad printed circuit boards and/or other conventional printed circuit boards. In some embodiments, the printed circuit board is used for surface mounting of electronic components thereon. The printed circuit board may include multiple LED components and any other device thereon, as well as one or more integrated circuit chip power supplies, integrated circuit chip LED controllers and/or other discrete and/or integrated circuit passive and/or active microelectronic components, such as surface mount components thereon.

Various embodiments of luminophoric layers comprising phosphor, optical coupling material, reflective layers and boards, are described, for example, in U.S. patent application Ser. No. 14/152,829 to Bhat et al. entitled “Wafer Level Contact Pad Solder Bumping for Surface Mount Devices With Non-Planar Recessed Contacting Surfaces”, U.S. patent application Ser. No. 14/201,490 to Bhat et al. entitled “Wafer Level Contact Pad Standoffs With Integrated Reflector”, and U.S. patent application Ser. No. 13/017,845 to Donofrio et al. entitled “Conformally Coated Light Emitting Devices and Methods for Providing the Same”, assigned to the assignee of the present application, the disclosures of which are hereby incorporated herein by reference in their entirety as if set forth fully herein.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

1. A Light Emitting Diode (LED) component comprising:
a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another;
an electrical connection element adjacent the first faces of the LED dies and configured to electrically connect the plurality of discrete LED dies in series and/or in parallel; and
a unitary optically transparent structure on the second faces of the LED dies remote from the anode and cathode contacts, that spans the plurality of LED dies.

2. An LED component according to claim 1 wherein the electrical connection element comprises a patterned metal sheet adjacent the first faces of the LED dies that is patterned to electrically connect the plurality of discrete LED dies in series and/or in parallel.

3. An LED component according to claim 1 wherein the electrical connection element comprises a plurality of wire bonds adjacent the first faces of the LED dies that are arranged to electrically connect the plurality of discrete LED dies in series and/or in parallel.

4. An LED component according to claim 2:
wherein the patterned metal sheet comprises first and second opposing faces, the LED dies being disposed on the first face of the patterned metal sheet such that the anode and cathode contacts are adjacent the first face of the patterned metal sheet and the second face of the patterned metal sheet is free of the submount thereon adjacent the plurality of LED dies;
the LED component further comprising a plurality of solder structures, a respective one of which electrically connects a respective one of the anode and cathode contacts to the patterned metal sheet;
the patterned metal sheet being patterned to selectively electrically connect the anode and cathode contacts of the LED dies in series and/or in parallel through the solder structures and to also provide an external anode contact and an external cathode contact for the LED component.

5. An LED component according to claim 1 further comprising:
a layer comprising luminophoric material on the second faces of the LED dies, between the second faces of the LED dies and the unitary optically transparent structure.

6. An LED component according to claim 5 wherein the layer comprising luminophoric material also extends on sidewalls of the LED dies.

7. An LED component according to claim 6 further comprising an optical coupling material between the unitary optically transparent structure and the layer comprising luminophoric material.

8. An LED component according to claim 1 wherein the unitary optically transparent structure is a unitary optically transparent sheet.

9. An LED component according to claim 8 wherein the unitary optically transparent sheet comprises a glass sheet.

10. An LED component according to claim 1 wherein the LED component is unsupported by a submount adjacent the first faces of the LED dies that spans the first faces of adjacent ones of the LED dies.

11. An LED component according to claim 2 wherein the LED dies are disposed on the patterned metal sheet such that the anode contacts of adjacent LED dies are adjacent one another and the cathode contacts of adjacent LED dies are adjacent one another, and the patterned metal sheet is patterned to electrically connect the anode contacts of the plurality of LED dies to one another and to electrically connect the cathode contacts of the plurality of LED dies to one another so that the plurality of LED dies are connected in parallel.

12. An LED component according to claim 2 wherein the LED dies are disposed on the patterned metal sheet such that the anode contacts of adjacent LED dies are opposite one another and the cathode contacts of adjacent LED dies are opposite one another, and the patterned metal sheet is patterned to electrically connect the anode contact and the cathode contact of adjacent LED dies to one another so that the plurality of LED dies are connected in series.

13. An LED component according to claim 1 further comprising:
a reflective layer on the first faces of the LED dies and extending between adjacent ones of the LED dies.

14. An LED component according to claim 1 on a board along with other electronic components, wherein the LED component is free of a submount between the plurality of LED dies and the board.

15. A Light Emitting Diode (LED) component comprising:
a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another;
a plurality of wire bonds adjacent the first faces of the LED dies that are configured to electrically connect the plurality of discrete LED dies in series and/or in parallel;
a plurality of solder structures, a respective one of which is on a respective one of the anode and cathode contacts; and
a unitary optically transparent structure on the second faces of the LED dies remote from the anode and cathode contacts, that spans the plurality of LED dies.

16. An LED component according to claim 15 further comprising:
a layer comprising luminophoric material on the second faces of the LED dies, between the second faces of the LED dies and the unitary optically transparent structure.

17. An LED component according to claim 16 wherein the layer comprising luminophoric material also extends on sidewalls of the LED dies.

18.-20. (canceled)

21. An LED component according to claim 15 wherein the LED component is unsupported by a submount adjacent the first faces of the LED dies that spans the first faces of adjacent ones of the LED dies.

22. An LED component according to claim 15, further comprising:
a reflective layer on the first faces of the LED dies and extending between adjacent ones of the LED dies.

23.-25. (canceled)

26. An LED component according to claim 15 on a board along with other electronic components, wherein the LED component is free of a submount between the plurality of LED dies and the board.

27. (canceled)

28. A Light Emitting Diode (LED) component comprising:
a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another;
a patterned metal sheet comprising first and second opposing faces, the LED dies being disposed on the first face of the patterned metal sheet such that the anode and cathode contacts are adjacent the first face of the patterned metal sheet and the second face of the patterned metal sheet is free of the submount thereon adjacent the plurality of LED dies;
a plurality of solder structures, a respective one of which electrically connects a respective one of the anode and cathode contacts to the patterned metal sheet;
wherein the patterned metal sheet is patterned to selectively electrically connect the anode and cathode contacts of the LED dies in series and/or in parallel through the solder structures and to also provide an external anode contact and an external cathode contact for the LED component; and
a unitary optically transparent structure on the second faces of the LED dies remote from the anode and cathode contacts, that spans the plurality of LED dies.

29. An LED component according to claim 28 further comprising:
a layer comprising luminophoric material on the second faces of the LED dies, between the second faces of the LED dies and the unitary optically transparent structure.

30. An LED component according to claim 29 wherein the layer comprising luminophoric material also extends on sidewalls of the LED dies.

31.-34. (canceled)

35. An LED component according to claim 28 further comprising:
a reflective layer on the first faces of the LED dies between the first faces of the LED dies and the patterned metal sheet, and extending between adjacent ones of the LED dies.

36.-38. (canceled)

39. An LED component according to claim 28 on a board along with other electronic components, wherein the LED component is free of a submount between the plurality of LED dies and the board.

40. A Light Emitting Diode (LED) component comprising:
a plurality of discrete LED dies that are spaced apart from one another, a respective one of which comprises first and second opposing faces and an anode contact and a cathode contact on the first face thereof, the plurality of discrete LED dies oriented such that the first faces of adjacent LED dies are adjacent one another and the second faces of adjacent LEDs are adjacent one another;
a patterned metal sheet comprising first and second opposing faces, the LED dies being disposed on the first face of the patterned metal sheet such that the anode and cathode contacts are adjacent the first face of the patterned metal sheet and the second face of the patterned metal sheet is free of the submount thereon adjacent the plurality of LED dies; and
a plurality of solder structures, a respective one of which electrically connects a respective one of the anode and cathode contacts to the patterned metal sheet;
wherein the patterned metal sheet is patterned to selectively electrically connect the anode and cathode contacts of the LED dies in series and/or in parallel through the solder structures and to also provide an external anode contact and an external cathode contact for the LED component; and
wherein the patterned metal sheet is configured as a polygonal cylinder, having a plurality of polygonal cylinder faces, wherein a respective LED die is on a respective polygonal cylinder face and wherein the patterned metal sheet connects adjacent polygonal cylinder faces to one another.

41. An LED component according to claim 40 further comprising:
a reflective layer on the first faces of the LED dies between the first faces of the LED dies and the patterned metal sheet.

42. An LED component according to claim 40 further comprising:
an optically transparent structure on a respective second face of a respective LED die remote from the anode and cathode contacts thereof.

43. An LED component according to claim 42 wherein a respective optically transparent structure comprises glass.

44. An LED component according to claim 41 wherein the reflective layer comprises white paint.

45. An LED component according to claim 40 on a board along with other electronic components, wherein the LED component is free of a submount between the plurality of LED dies and the board.

46. An LED component according to claim 42 further comprising:
a layer comprising luminophoric material on the second faces of the LED dies, between the second faces of the LED dies and a respective optically transparent structure.

47. An LED component according to claim 46 wherein the layer comprising luminophoric material also extends on sidewalls of the LED dies.

48.-51. (canceled)

52. A method of fabricating a Light Emitting Diode (LED) component, the method comprising:
placing a plurality of discrete LED dies on a carrier sheet in spaced apart relation from one another, a respective LED die comprising first and second opposing faces and an anode contact and a cathode contact on the first face thereof, the plurality of discrete LED dies being oriented on the carrier sheet such that the first faces of adjacent LED dies are adjacent the carrier sheet and the second faces of adjacent LEDs are remote from the carrier sheet;
coating a luminophoric layer on the second faces and sidewalls of the LED dies on the carrier sheet;
placing a unitary optically transparent structure on the second faces of the LED dies so that the unitary optically transparent structure spans the LED dies;
removing the carrier sheet such that the unitary optically transparent structure supports the plurality of discrete LED dies thereon;
selectively electrically connecting the plurality of discrete LED dies that are on the unitary optically transparent structure in series and/or in parallel;
applying a reflective layer on the first faces of the LED dies and extending between adjacent ones of the LED dies;
singulating groups of the LED dies that are connected in series/and or in parallel to provide a plurality of the LED components, a respective LED component being unsupported by a submount adjacent the first faces of the LED dies that spans the first faces of adjacent ones of the LED dies.

53.-61. (canceled)
